(19) United States
(12) Patent Application Publication
(10) Pub. No.: US 2008/0213991 A1
(43) Pub. Date: Sep. 4, 2008

(54) Method of forming plugs

(75) Inventors: Wen-Jiunn Tsay, Taipei Hsien (TW); Bao-Tai Hwang, Taipei Hsien (TW); David Yow-Chern Chang, Taipei Hsien (TW); Ling-Haur Huang, Taipei Hsien (TW)

Correspondence Address: Joe McKinney Muncy, PO Box 1364, Fairfax, VA, 22038-1364, US

(73) Assignee: AirDio Wireless Inc.

(21) Appl. No.: 11/713,038

(22) Filed: Mar. 2, 2007

(51) Int. Cl. H01L 21/44

(52) U.S. Cl. 438/597

(57) ABSTRACT

The present invention is a method of forming plugs for engaging with a socket on a substrate having pads thereon. The method including the steps of forming an insulation layer on the substrate, patterning the insulation layer to form openings for exposing the pads by a wet etching, respectively, forming conductive plugs in the openings to electrically connect with the pads, and partially removing the insulation layer.

### BACKGROUND

1. Field of Invention

The present invention relates to a method of forming plugs on a substrate. More particularly, the present invention relates to a method of forming plugs for engaging with a test socket on a substrate.

2. Description of Related Art

In recent years, the integrated circuit packaging industry has adapted wafer level packaging (WLP) technology to provide smaller, thinner and less parasitic packages. In order to test the WLP chips, plugs are formed on top of the pads of the substrate so that a probe or a test socket may engage with the plugs to perform the necessary tests. Various plug forming techniques have developed, but the bottleneck is at the plugs are not formed in the shape suitable for test socket engagement; therefore plugs for socket testing cannot be realized. A preferred plug shape for test socket engagement is a shape resembling a bowl with a wider top surface, with the edges slanted inwardly towards a smaller base surface. Such shape will allow the test sockets to have a large connect surface with the plugs and also establish a grip with the plugs. Plug forming methods such as direct plating of a metal sheet on top of the semiconductor substrate and than etch out individual plugs cannot provide such shaping. Plug forming methods such as directly growing plugs on top of the pads of the wafer cannot provide such shaping, because growing plugs from the bottom up cannot result in a bowl shape. Please refer to FIG. 1, an exemplary cross section view of a plug 102 on the pads 104 of a wafer 106. Notice the shape of the plug 102 has a smaller top surface and becomes wider at the bottom area. The exemplary shape is not suitable for test socket engagement due to the small horizontal contact surface and does not have adequate gripping area.

For the forgoing reasons, there is a need for a method of shaping plugs to form plugs suitable for wafer level test socket engagement.

### SUMMARY

The present invention is directed to a method of forming plugs, that is satisfies this need of forming plugs for engaging with a test socket. The method comprises forming an insulation layer on the substrate, patterning the insulation layer to form openings for exposing the pads by a wet etching, respectively, forming conductive plugs in the openings to electrically connect with the pads, and partially removing the insulation layer. The opening formed by the wet etching process will resemble a wider opening towards the top surface of the wafer substrate and a narrower space towards the pads on the substrate. The curve of the etched side wall of the insulation layer may vary due to the unpredictable etch rate of the wet etching process. However, the overall shape of the opening will still resemble a similar shape as a bowl, suitable for test socket engagement.

The protrusion of the plugs may be controlled by the amount of partial removal done to the insulation layer after the forming of the plugs. By doing so, one can determine how much protrusion is necessary for test socket engagement.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is an exemplary cross section view of a plug on the pads of a substrate;

FIG. 2 is a flow chart of the method of forming plugs for test socket engagement according to one embodiment of the present invention;

FIG. 3 is a cross section view of the substrate in step 202;

FIG. 4 is a cross section view of the substrate in step 204;

FIG. 5 is a cross section view of the substrate in step 204;

FIG. 6 is a cross section view of the substrate in step 204;

FIG. 7 is a cross section view of the substrate in step 206;

FIG. 8 is a cross section view of the substrate in step 208;

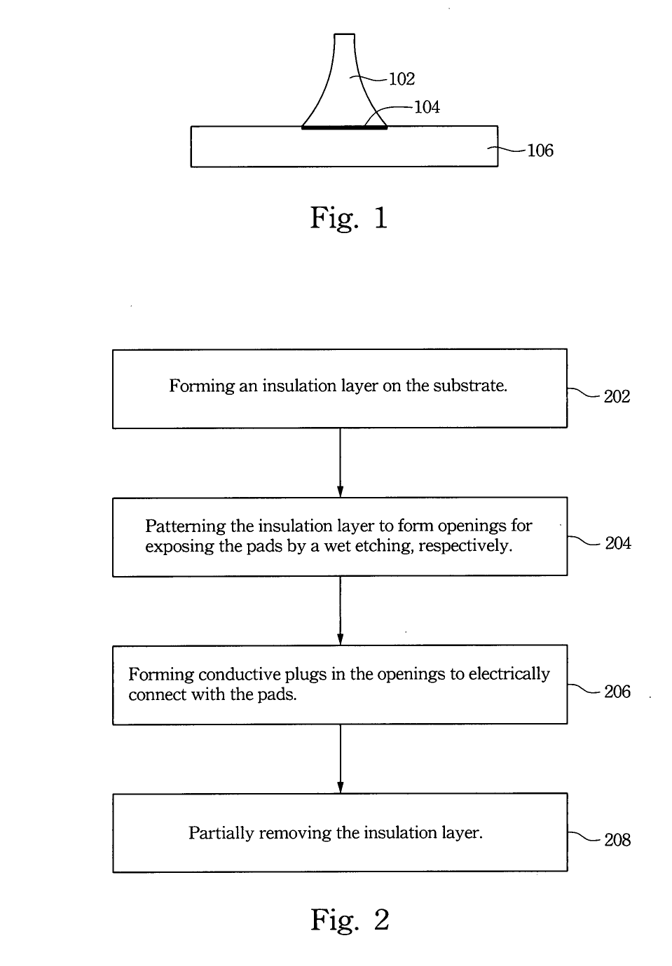

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Please refer to FIG. 2, a flow chart of the method of forming plugs for test socket engagement according to one embodiment of the present invention. The method includes step 202, forming an insulation layer on the substrate. In step 204, patterning the insulation layer to form openings for exposing the pads by a wet etching, respectively. In step 206, forming conductive plugs in the openings to electrically connect with the pads. In step 208, partially removing the insulation layer.

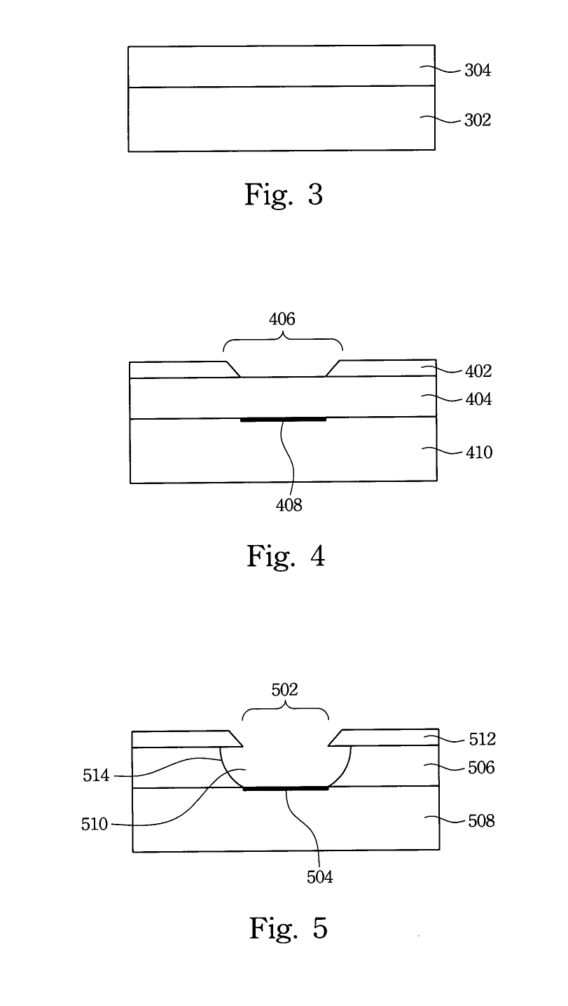

Please refer to FIG. 3, a cross section view of the wafer in step 202. The wafer 302 has integrated chips fabricated (not shown) thereon. The insulation layer 304 may be a borophosphosilicate glass layer, a borosilicate glass layer, a phosphosilicate layer, a silicon oxide layer, a silicon oxynitride layer or a silicon nitride layer. The disposition of the insulation layer 304 may be a multiple layer deposition depending on the desired thickness of the insulation layer 304.

In step 204, patterning the insulation layer to form openings for exposing the pads includes a lithography process and a wet etching process. Furthermore, the lithography process includes forming a photoresist layer on top of the insulation layer, exposing the photoresist layer and developing the substrate to remove the photoresist layer in the vertically extended regions on top of the pads. The wet etching process includes applying an etchant solution to the substrate, monitoring the chemical reaction of the etchant solution with the insulation layer until the pads on the substrate are exposed, and removing the etchant solution and the photoresist layer from the substrate. The patterning step is further illustrated in FIG. 4, 5 and 6 as follows.

Please refer to FIG. 4, a cross section view of the wafer substrate in step 204. A photoresist layer 402 is disposed on top of the insulation layer 404. The photoresist layer 402 is exposed by an optical source (not shown) through a mask (not shown) with a predetermined pattern. After exposure, the wafer 410 is developed to remove the photoresist layer 402 in the vertically extended regions 406 on top of the pads 408.

Please refer to FIG. 5, a cross section view of the wafer in step 204. An etchant solution such as sulfuric acid, hydrofluoric acid, nitric acid, phosphoric acid, acetic acid, and mixtures thereof is applied to the surface of the substrate. The etchant solution is able to etch away the material in the vertically extended regions 502 on top of the pads 504. After the etchant solution is applied, the chemical reaction of the etchant solution with the insulation layer 506 is monitored and controlled until the pads 504 on the wafer substrate 508 is exposed. Lastly, remove the etchant solution from the surface of the wafer substrate 508 to discontinue the etching reaction. Notice the shape of the opening 510 is wider toward the photoresist layer 512 and becomes narrower toward the pads 504. The side walls 514 of the opening 510 are curved with the degree of curvature dependent on the material of the insulation layer 506 and the content of the etchant solution. The opening profile is the result of the wet etching process giving an isotropic profile. The etchant solution begins etching form the top of the insulation layer 506 and etches in all directions into the insulation layer 506. Thus, the opening 510 at the top will undergo longer etched time than the opening 510 at the bottom, resulting in a bowl shape profile. This opening profile is a must for forming plugs for test socket engagement.

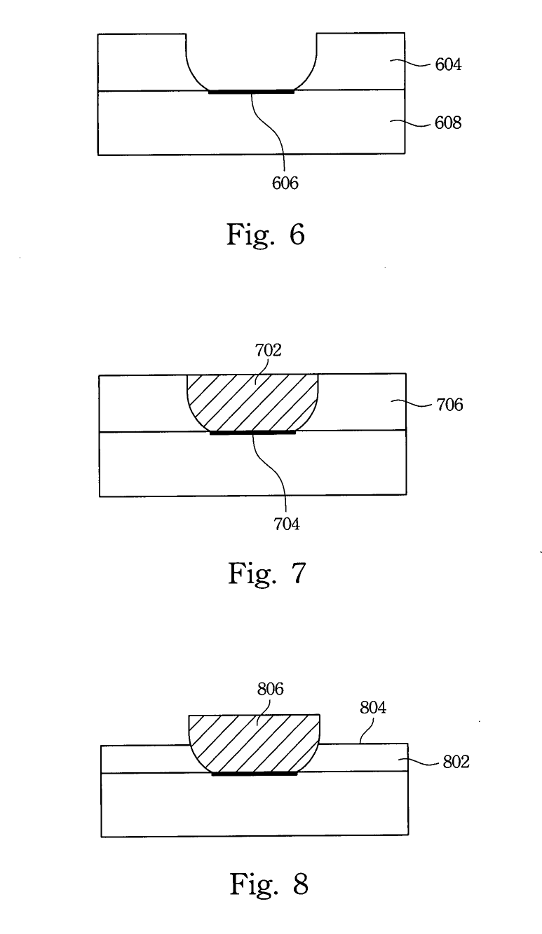

Please refer to FIG. 6, the cross section view of the wafer in step 204. The photoresist layer 512 is removed to expose the entire insulation layer 604 and the pads 606 on the wafer substrate 608.

Next, please refer to FIG. 7, the cross section view of the wafer in step 206. A plug 702 is formed in the opening 510. The plug 702 is formed into a shape identical to the opening 510 and is electrically connected to the pad 704. The plug 702 may be formed by a metalization process, a plating process, a chemical vapor deposition process, a physical vapor deposition process, or a combination thereof. The above mentioned plugs forming process will result in a metal layer (not shown) filling the openings 510 and also onto the surface of the insulation layer 706. Therefore, the metal on the surface of the insulation layer is to be removed, leaving only the plug 702 in the opening 510 on the pads 704. The material of the plug 702 may be metal alloys such as copper alloys, aluminum alloys, or any metal with good electrically conduction and hardness able to sustain test socket engagement stress tests.

Lastly, please refer to FIG. 8, the cross section view of the wafer in step 208. The insulation layer 802 is etched with the etchant solution such as the solutions in step 206 to partially remove the insulation layer 802, reducing its thickness and thus allowing the plugs to protrude out of the substrate surface 804. The amount of protrusion may be controlled by controlling the etch time. Various test socket configurations may need different amount of protrusion. The protrusion will allow the test sockets to grip onto the sides of the plug 806 and the wide top surface provides concrete interface between the plug 806 and the test socket (not shown).

The present invention is a method of forming plugs for test socket engagement. The plugs are formed to have a wider top surface and a narrow base surface to provide a suitable contact interface for test socket engagement.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of forming plugs for engaging with a socket on a substrate having pads thereon, the method comprising:
(a) forming an insulation layer on the substrate;
(b) patterning the insulation layer to form openings for exposing the pads by a wet etching, respectively;
(c) forming conductive plugs in the openings to electrically connect with the pads; and
(d) partially removing the insulation layer to allow the conductive plugs to protrude out of a surface of the insulation layer for socket engagement.

2. The method of claim 1, wherein the insulation layer is a borophosphosilicate glass layer, a borosilicate glass layer, a phosphosilicate layer, a silicon oxide layer, a silicon oxynitride layer or a silicon nitride layer.

3. The method of claim 1, wherein the patterning step comprises the steps of:
performing a lithography process on the substrate to expose the insulation layer in the vertically extended region of the pads; and
performing a wet etching on the substrate to form opening for exposing the pads.

4. The method of claim 3, wherein the lithography process comprises the steps of:
forming a photoresist layer on top of the insulation layer;
exposing the photoresist layer to an optical source through a mask; and
developing the substrate to remove the photoresist layer in the vertically extended regions on top of the pads.

5. The method of claim 3, wherein the wet etching step comprising the steps of:
applying an etchant solution to the substrate;
monitoring the chemical reaction of the etchant solution with the insulation layer until the pads on the substrate are exposed; and
removing the etchant solution and the photoresist layer from the substrate.

6. The method of claim 1, wherein a material of the plugs is a copper alloy.

7. The method of claim 1, wherein the material of the plugs is a aluminum alloy.

8. The method of claim 1, wherein the plugs are formed by a metalization process, a plating process, a chemical vapor deposition process, a physical deposition process, and a combination thereof.

9. The method of claim 1, wherein the plugs having identical shape as the opening.

10. The method of claim 9, wherein the openings having a shape of a bowl.

11. The method of claim 1, wherein the partially removing of the insulation layer is removing a thickness of the insulation layer to control an amount of protrusion of the conductive plugs for socket engagement.

12. The method of claim 11, wherein the partially removing of the insulation layer comprising the steps of:
applying an etchant solution to the substrate;
monitoring the chemical reaction of the etchant solution with the insulation layer allowing the thickness of the insulation layer to reduce to the desired thickness measurement; and
removing the etchant solution from the substrate.

13. The method of claim 1, wherein the socket is a test socket.
